(19) United States
(12) Patent Application Publication
(10) Pub. No.: US 2022/0013689 A1
(43) Pub. Date: Jan. 13, 2022

(54) MICRO-LED DEVICE AND MANUFACTURING METHOD THEREOF

(71) Applicant: SAKAI DISPLAY PRODUCTS CORPORATION, Sakai-shi, Osaka (JP)

(72) Inventor: KATSUHIKO KISHIMOTO, Sakai-shi, Osaka (JP)

(73) Assignee: SAKAI DISPLAY PRODUCTS CORPORATION, Sakai-shi, Osaka (JP)

(21) Appl. No.: 17/417,761

(22) PCT Filed: Dec. 27, 2018
(86) PCT No.: PCT/JP2018/048350

§ 371 Date: Jun. 24, 2021

(51) Int. Cl. H01L 33/16; H01L 33/62; H01L 33/38; H01L 25/075

(52) U.S. Cl. CPC H01L 33/16; H01L 25/0756; H01L 33/387; H01L 33/62

(57) ABSTRACT

A micro-LED device of the present disclosure includes a crystal growth substrate (100) having an upper surface covered with a mask layer (150), the mask layer having a plurality of openings (150G), and a frontplane (200) that includes a plurality of micro-LEDs (220), each of which includes one or a plurality of semiconductor rods having a first semiconductor layer of a first conductivity type and a second semiconductor layer of a second conductivity type, and a device isolation region (240) located between the micro-LEDs. The device isolation region includes at least one metal plug (24) electrically coupled with the second semiconductor layer. This device includes a middle layer (300) which includes first contact electrodes (31) electrically coupled with the first semiconductor layer and a second contact electrode (32) coupled with the metal plug, and a backplane (400) provided on the middle layer.

### TECHNICAL FIELD

The present disclosure relates to a micro-LED device and a method for producing the same.

### BACKGROUND ART

To realize a practical display device which includes a large number of micro-LEDs arrayed at a narrow pitch, it is necessary to develop mass production techniques for mounting microscopic micro-LEDs at predetermined positions on a circuit board such as TFT substrate. According to the technique of mounting each of the micro-LEDs to a circuit by a pick-and-place method, mounting a large number of micro-LEDs to a circuit at a pitch of, for example, several tens of micrometers needs a very long work time.

Patent Document No. 1 discloses a display device which includes a large number of micro-LEDs transferred onto a TFT substrate and a method for producing the display device.

Patent Document No. 2 discloses a display device that includes a GaN wafer where a plurality of LEDs are formed and a backplane control section (TFT substrate) to which the GaN wafer is joined and a method for producing the display device.

### CITATION LIST

### Patent Literature

Patent Document No. 1: Japanese PCT National Phase Laid-Open Patent Publication No. 2016-522585
Patent Document No. 2: Japanese PCT National Phase Laid-Open Patent Publication No. 2017-538290

### SUMMARY OF INVENTION

### Technical Problem

The method of transferring a large number of micro-LEDs onto a TFT substrate has greater difficulty in positioning the micro-LEDs relative to the TFT substrate as the size of the micro-LEDs decreases and the number of the micro-LEDs increases. The method of joining a GaN wafer to a backplane control section needs a complicated step which includes transferring a GaN wafer to another wafer for temporal storage and then mounting it to the backplane control section.

The present disclosure provides a novel configuration and production method of a micro-LED device, which can solve the above-described problems.

### Solution to Problem

A micro-LED device of the present disclosure includes, in an exemplary embodiment: a crystal growth substrate having an upper surface covered with a mask layer, the mask layer having a plurality of openings; a frontplane supported by the crystal growth substrate, the frontplane including a plurality of micro-LEDs, each of which includes one or a plurality of semiconductor rods having a first semiconductor layer of a first conductivity type and a second semiconductor layer of a second conductivity type, and a device isolation region located between the plurality of micro-LEDs, the device isolation region including at least one metal plug electrically coupled with the second semiconductor layer; a middle layer supported by the frontplane, the middle layer including a plurality of first contact electrodes respectively electrically coupled with the first semiconductor layer of the plurality of micro-LEDs and at least one second contact electrode coupled with the metal plug; and a backplane supported by the middle layer, the backplane including an electric circuit electrically coupled with the plurality of micro-LEDs via the plurality of first contact electrodes and the at least one second contact electrode, the electric circuit including a plurality of thin film transistors. The crystal growth substrate has an electrically-conductive surface, the plurality of openings of the mask layer includes a plurality of mask openings which respectively define a position of the semiconductor rods and a contact opening for coupling the metal plug with the electrically-conductive surface of the crystal growth substrate, and each of the plurality of thin film transistors includes a semiconductor layer deposited on the frontplane and/or the middle layer.

In one embodiment, the plurality of micro-LEDs include a first micro-LED capable of emitting light at a first wavelength and a second micro-LED capable of emitting light at a second wavelength that is different from the first wavelength, and a thickness of the plurality of semiconductor rods which form the first semiconductor layer and the second semiconductor layer of the first micro-LED is different from a thickness of the plurality of semiconductor rods which form the first semiconductor layer and the second semiconductor layer of the second micro-LED.

In one embodiment, the plurality of mask openings include a plurality of first mask openings and a plurality of second mask openings each having a size and/or shape different from a size and/or shape of each of the first mask openings.

In one embodiment, the mask layer is made of an electrically-conductive material and mutually electrically couples the second semiconductor layers of the plurality of micro-LEDs.

In one embodiment, the crystal growth substrate includes a titanium nitride layer extending along the upper surface.

In one embodiment, the crystal growth substrate includes a surface semiconductor region of the second conductivity type extending along the upper surface.

In one embodiment, the device isolation region of the frontplane includes an embedded insulator filling a gap between the plurality of micro-LEDs, the embedded insulator having at least one through hole for the metal plug.

In one embodiment, the device isolation region of the frontplane includes a plurality of insulating layers covering a side surface of the plurality of micro-LEDs, and the metal plug fills a space in the device isolation region which is surrounded by the plurality of insulating layers.

In one embodiment, the frontplane has a flat surface, and the flat surface is in contact with the middle layer.

In one embodiment, the middle layer includes an interlayer insulating layer having a flat surface, and the interlayer insulating layer has a plurality of contact holes for coupling the plurality of first contact electrodes and the at least one second contact electrode with the electric circuit.

In one embodiment, the electric circuit of the backplane includes a plurality of metal layers respectively coupled with the plurality of first contact electrodes and the at least one second contact electrode, and the plurality of metal layers include at least one of a source electrode and a drain electrode of the plurality of thin film transistors.

In one embodiment, each of the plurality of micro-LEDs is capable of radiating a visible, ultraviolet, or infrared electromagnetic wave.

A micro-LED device production method of the present disclosure includes, in an exemplary embodiment: providing a multilayer stack which includes a frontplane supported by a crystal growth substrate which has an electrically-conductive surface, the frontplane including a plurality of micro-LEDs, each of which includes one or a plurality of semiconductor rods having a first semiconductor layer of a first conductivity type and a second semiconductor layer of a second conductivity type, and a device isolation region located between the plurality of micro-LEDs, the device isolation region including at least one metal plug electrically coupled with the second semiconductor layer, and a middle layer supported by the frontplane, the middle layer including a plurality of first contact electrodes respectively electrically coupled with the first semiconductor layer of the plurality of micro-LEDs and at least one second contact electrode coupled with the metal plug; and forming a backplane on the multilayer stack, the backplane including an electric circuit electrically coupled with the plurality of micro-LEDs via the plurality of first contact electrodes and the at least one second contact electrode, the electric circuit including a plurality of thin film transistors. Providing the multilayer stack includes selectively epitaxially growing the semiconductor rods from a plurality of predetermined regions of an upper surface of the crystal growth substrate, and forming the backplane includes depositing a semiconductor layer on the multilayer stack, and patterning the semiconductor layer deposited on the multilayer stack.

In one embodiment, providing the multilayer stack includes forming a mask layer so as to cover the electrically-conductive surface of the crystal growth substrate, the mask layer having a plurality of mask openings which define a position of the semiconductor rods included in each of the plurality of micro-LEDs, and selectively epitaxially growing the semiconductor rods from the plurality of mask openings.

In one embodiment, providing the multilayer stack includes, after selectively epitaxially growing the semiconductor rods from the plurality of mask openings, forming a contact opening in the mask layer for coupling the metal plug with the electrically-conductive surface of the crystal growth substrate.

In one embodiment, the mask openings have a size determined according to an emission wavelength of each of the micro-LEDs.

### Advantageous Effects of Invention

According to an embodiment of the present invention, a micro-LED device and a production method thereof are provided which can solve the above-described problems.

### BRIEF DESCRIPTION OF DRAWINGS

FIG. 1A is a cross-sectional view showing part of a μLED device 1000 of the present disclosure.

FIG. 1B is a plan view showing an arrangement example of μLEDs 220 in the μLED device 1000.

FIG. 1C is a plan view showing an arrangement example of semiconductor rods in the μLEDs 220.

FIG. 1D is a plan view showing an arrangement example of metal plugs 24 in the μLED device 1000.

FIG. 1E is a plan view showing another arrangement example of a metal plug 24 in the μLED device 1000.

FIG. 2 is a perspective view showing an arrangement example of first contact electrodes 31 and second contact electrodes 32 in the μLED device 1000.

FIG. 3 is a circuit diagram showing an example of part of an electric circuit in the μLED device 1000.

FIG. 4A is a perspective view schematically showing a production step of the μLED device 1000.

FIG. 4B is a perspective view schematically showing a production step of the μLED device 1000.

FIG. 4C is a perspective view schematically showing a production step of the μLED device 1000.

FIG. 4D is a perspective view schematically showing a production step of the μLED device 1000.

FIG. 4E is a perspective view schematically showing a production step of the μLED device 1000.

FIG. 4F is a perspective view schematically showing a production step of the μLED device 1000.

FIG. 4G is a perspective view schematically showing a production step of the μLED device 1000.

FIG. 5 is a cross-sectional view of a μLED device 1000A in an embodiment of the present disclosure.

FIG. 6A is a cross-sectional view schematically showing a production step of the μLED device 1000A.

FIG. 6B is a cross-sectional view schematically showing a production step of the μLED device 1000A.

FIG. 6C is a cross-sectional view schematically showing a production step of the μLED device 1000A.

FIG. 6D is a cross-sectional view schematically showing a production step of the μLED device 1000A.

FIG. 6E is a cross-sectional view schematically showing a production step of the μLED device 1000A.

FIG. 6F is a cross-sectional view schematically showing a production step of the μLED device 1000A.

FIG. 6G is a cross-sectional view schematically showing a production step of the μLED device 1000A.

FIG. 7 is a cross-sectional view showing another configuration example of the μLED device 1000A in an embodiment of the present disclosure.

FIG. 8 is a cross-sectional view showing still another configuration example of the μLED device 1000A in an embodiment of the present disclosure.

### DESCRIPTION OF EMBODIMENTS

### Definitions

In the present disclosure, “micro-LED” means a light emitting diode (LED) whose occupation region can be included within an area of 100 μm×100 μm. “Light” emitted by the micro-LED is not limited to visible light but includes a wide variety of electromagnetic waves including visible, ultraviolet, and infrared. Hereinafter, “micro-LED” is also referred to as “μLED”.

The μLED includes one or a plurality of semiconductor rods. When a single μLED includes a plurality of semiconductor rods, the plurality of semiconductor rods are driven by a common electrode. Each of the semiconductor rods has a first semiconductor layer of the first conductivity type and a second semiconductor layer of the second conductivity type. The first conductivity type is one of p-type and n-type. The second conductivity type is the other of p-type and n-type. For example, if the first conductivity type is p-type, the second conductivity type is n-type. If, on the contrary, the first conductivity type is n-type, the second conductivity type is p-type. Each of the first semiconductor layer and the second semiconductor layer can have a single-layer structure or a multilayer structure. Typically, an emission layer which has at least one quantum well (or double heterostructure) is provided between the first semiconductor layer and the second semiconductor layer.

In the present disclosure, “micro-LED device (μLED device)” refers to a device which includes a plurality of μLEDs. The plurality of μLEDs in the μLED device are also referred to as “μLED array”. A typical example of the μLED device is a display device, although the μLED device is not limited to a display device.

<Basic Configuration>

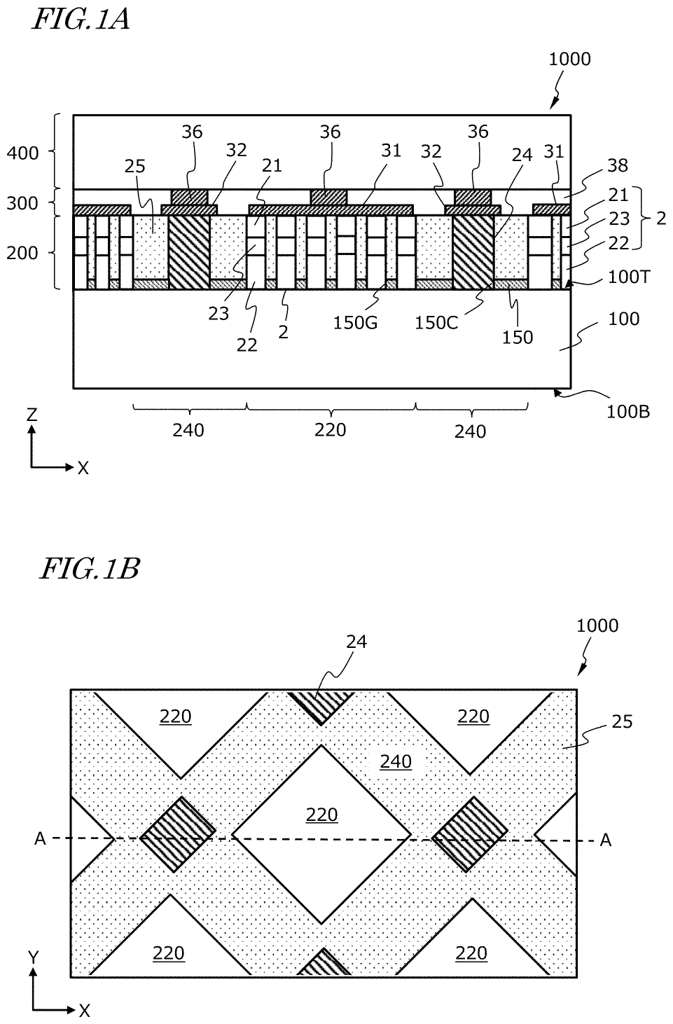

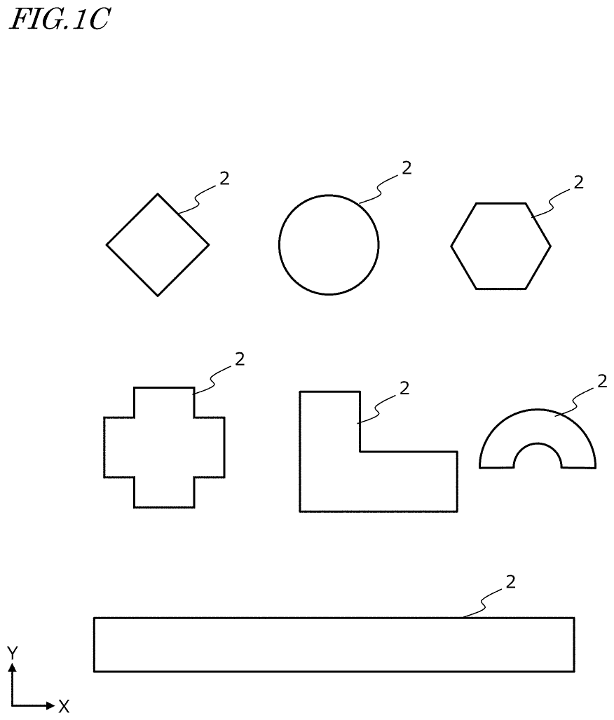

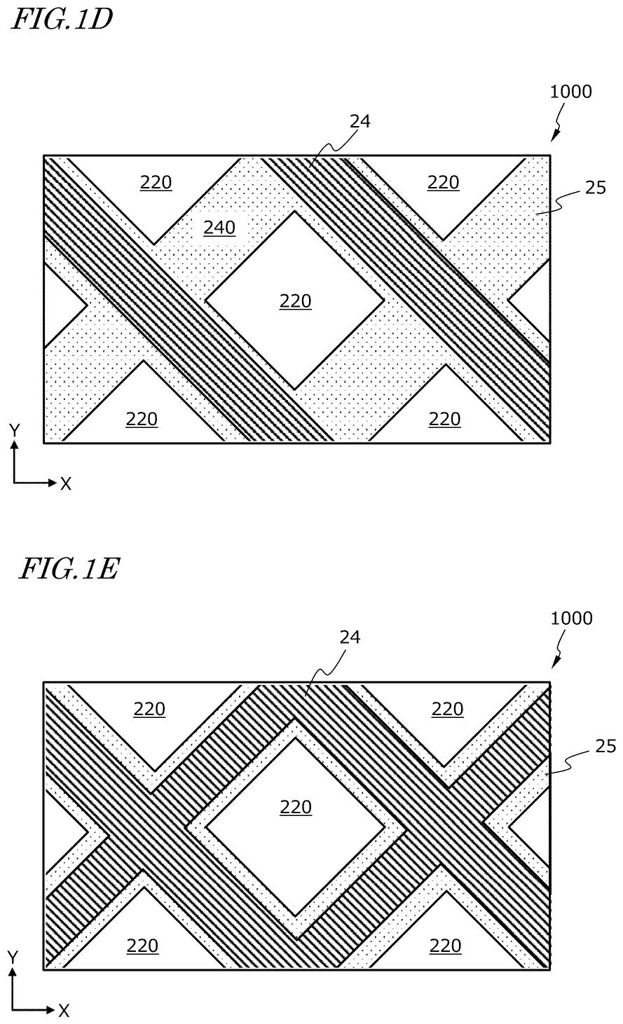

A basic configuration example of a μLED device of the present disclosure is described with reference to FIG. 1A and FIG. 1B. FIG. 1A is a cross-sectional view showing part of a μLED device 1000. FIG. 1B is a plan view showing an arrangement example of a μLED array in the μLED device 1000. The cross section of the μLED device 1000 shown in FIG. 1A is identical with the cross section taken along line A-A of FIG. 1B.

The μLED device 1000 can include a large number of μLEDs, for example, more than 1,000,000 μLEDs. FIG. 1A and FIG. 1B show only a part of the μLED device 1000 which includes several μLEDs. The entirety of the μLED device 1000 has a configuration where the shown part is periodically repeated.

The μLED device 1000 includes a crystal growth substrate 100, a frontplane 200 supported by the crystal growth substrate 100, a middle layer 300 supported by the frontplane 200, and a backplane 400 supported by the middle layer.

In the attached drawings, the proportion of the transverse size to the longitudinal size of respective components such as μLEDs is not necessarily equal to the actual proportion in an embodiment. In the drawings, clarity takes precedence in determining the proportion of the depicted components. The orientation of respective components in the drawings does not limit at all the orientation in actual production of the μLED device and the orientation in actual use of the μLED device. In FIG. 1A and FIG. 1B, a right-handed coordinate system of X-axis, Y-axis and Z-axis, which are mutually orthogonal, is shown for reference.

<Crystal Growth Substrate>

The crystal growth substrate 100 is a substrate on which semiconductor crystals, which are constituents of the μLEDs, are to epitaxially grow. Hereinafter, such a crystal growth substrate is simply referred to as “substrate”. A surface 100T of the substrate 100 on which crystal growth occurs is referred to as “upper surface” or “crystal growth surface”. Another surface 100B of the substrate 100 which is opposite to the surface 100T is referred to as “lower surface”. In this specification, the terms “upper surface” and “lower surface” do not depend on the actual orientation of the substrate 100 when they are used.

A typical example of semiconductor crystals which can be used in embodiments of the present disclosure is a gallium nitride based compound semiconductor. Hereinafter, the gallium nitride based compound semiconductor is also referred to as “GaN”. Some of gallium (Ga) atoms in GaN may be substituted with aluminum (Al) atoms or indium (In) atoms. GaN in which some of Ga atoms are substituted with Al atoms is also referred to as “AlGaN”. GaN in which some of Ga atoms are substituted with In atoms is also referred to as “InGaN”. GaN in which some of Ga atoms are substituted with Al atoms and In atoms is also referred to as “AlInGaN” or “InAlGaN”. The bandgap of GaN is smaller than the bandgap of AlGaN but greater than the bandgap of InGaN. In the present disclosure, gallium nitride based compound semiconductors in which some of constituent atoms are substituted with other atoms are also generically referred to as “GaN”. “GaN” can be doped with an n-type impurity and/or a p-type impurity as impurity ion. GaN whose conductivity type is n-type is referred to as “n-GaN”. GaN whose conductivity type is p-type is referred to as “p-GaN”. Details of the method of growing semiconductor crystals will be described later. In the embodiments of the present disclosure, semiconductor crystals which are constituents of the μLED are not limited to GaN-based semiconductors but may be made of a nitride semiconductor such as AlN, InN, or AlInN, or any other type of semiconductor.

In the present disclosure, the substrate 100 has an electrically-conductive surface. The upper surface 100T of the substrate 100 is covered with a mask layer 150 which has a plurality of openings. The mask layer 150 can be made of, for example, a refractory metal such as titanium (Ti) and tantalum (Ta) (electrically-conductive material) and/or an insulative material such as silicon dioxide and silicon nitride. The plurality of openings include a plurality of mask openings 150G which define the position and arrangement of a plurality of semiconductor rods 2 included in a plurality of μLEDs 220 that will be described later and a contact opening 150C for coupling a metal plug 24 with the upper surface 100T of the substrate 100.

Examples of the substrate 100 include sapphire substrates, GaN substrates, SiC substrates, and Si substrates which have an electrically-conductive surface. When the substrate 100 is a sapphire substrate, the upper surface of the sapphire substrate is provided with an electrically-conductive layer which is not shown in FIG. 1A. Examples of the electrically-conductive layer include a titanium nitride (TiN) layer and/or a semiconductor layer doped with an impurity element (a surface semiconductor region of the second conductivity type). When the substrate 100 is a GaN substrate, a SiC substrate, or a Si substrate, an electrically-conductive surface is formed at the surface of the substrate by doping with an impurity or by epitaxially growing an electrically-conductive layer (buffer layer).

In an embodiment of the present disclosure, the substrate 100 is a constituent of a final μLED device 1000. The thickness of the substrate 100 can be, for example, not less than 30 μm and not more than 1000 μm, preferably not more than 500 μm. Since the role of the substrate 100 is the base for crystal growth, the rigidity of the μLED device 1000 may be compensated for with any other rigid member than the substrate 100. Such a rigid member can be fixed to the backplane 400, for example. During the production process, a supporting substrate (not shown) for compensating for the rigidity of the substrate 100 may be secured to the lower surface 100B of the substrate 100. Such a supporting substrate may be removed from a final μLED device 1000 or may be used while it is kept fixed to the substrate 100.

When light radiated from a μLED array is transmitted through the substrate 100 for displaying or the like, it is desirable that the substrate 100 is made of a material which exhibits high light-transmissiveness in the wavelength band of the light. An example of the material which exhibits high light-transmissiveness for ultraviolet and visible light is sapphire. An example of the material which exhibits high light-transmissiveness for ultraviolet at the wavelength of 380 nm or longer and visible light is GaN.

When light radiated from a μLED array is transmitted through the backplane 400 for displaying or the like, the substrate 100 does not need to transmit the light. The embodiments of the present disclosure can include an embodiment where light radiated from a μLED array is transmitted through both the substrate 100 and the backplane 400 for displaying on opposite surfaces.

The upper surface (crystal growth surface) 100T of the substrate 100 may have a structure for relieving the crystal lattice mismatch, such as grooves or ridges. The lower surface 100B of the substrate 100 may have microscopic irregularities for improving the extraction efficiency of light radiated from a μLED array and then transmitted through the substrate 100 or for diffusing the light. Examples of the microscopic irregularities include a moth-eye structure. The moth-eye structure continuously changes the effective refractive index across the lower surface 100B of the substrate 100 and, therefore, the proportion of light reflected by the lower surface 100B of the substrate 100 to the inside of the substrate 100 (reflectance) can be greatly reduced (to substantially zero).

In the present disclosure, the positive direction of Z axis shown in FIG. 1A (the direction of the arrow) is also referred to as “crystal growth direction” or “semiconductor layering direction”. The lower surface 100B and the upper surface 100T of the substrate 100 may be referred to as “front surface” and “rear surface”, respectively, of the substrate 100. The relative positional relationship between “front surface” and “rear surface” does not depend on whether or not the μLED device 1000 is a device which utilizes light transmitted through the substrate 100.

<Frontplane>

The frontplane 200 includes a plurality of μLEDs 220 and a device isolation region 240 located between the plurality of μLEDs 220. The plurality of μLEDs 220 can be arrayed in rows and columns in a two-dimensional plane (XY plane) which is parallel to the upper surface 100T of the substrate 100. In the example shown in the drawing, each of the plurality of μLEDs 220 includes a plurality of semiconductor rods 2 respectively extending from a plurality of mask openings 150G of a mask layer 150 as shown in FIG. 1A. Each of the semiconductor rods 2 includes a first semiconductor layer 21 of the first conductivity type and a second semiconductor layer 22 of the second conductivity type. A cross section of a single μLED 220 illustrated in the central part of FIG. 1A includes cross sections of six upright semiconductor rods 2 which are schematically illustrated. In each of the semiconductor rods 2, a part of the first conductivity type forms the first semiconductor layer 21, and a part of the second conductivity type forms the second semiconductor layer 22. In addition, in each of the semiconductor rods 2, a part extending between the part that forms the first semiconductor layer 21 and the part that forms the second semiconductor layer 22 forms an emission layer 23. The number of semiconductor rods 2 included in each of the μLEDs 220 is not limited to the illustrated example but can be, for example, 1 to 100 or greater. The thickness (the diameter or the long axis size of the cross section) of each of the semiconductor rods 2 can be, for example, 50 nm to 50 μm.

FIG. 1C is a plan view showing an arrangement example of semiconductor rods 2 included in each of the μLEDs 220. As illustrated in FIG. 1C, the cross-sectional shape of the semiconductor rods 2 (the shape of the semiconductor rods 2 in a cross section parallel to the upper surface 100T of the substrate 100) can be various. For example, the cross-sectional shape of the semiconductor rods 2 may be a polygonal shape, such as triangle, square, rectangle, rhombus, parallelogram, pentagon, hexagon, and etc., a circular shape, an elliptical shape, or a shape which at least partially includes a curve. The cross-sectional shape of the semiconductor rods 2 may have a convex and/or concave contour in a plane parallel to the upper surface 100T of the substrate 100 or may have a long axis portion elongated at least in one direction.

When each of the μLEDs 220 includes a plurality of semiconductor rods 2, the semiconductor rods 2 may be arrayed in rows and columns in a plane parallel to the upper surface 100T of the substrate 100 or may be arrayed on concentric circles, a curve line, a meander line, or a bent line. Alternatively, the semiconductor rods 2 may be irregularly arranged. Still alternatively, each of the μLEDs 220 may include a plurality of semiconductor rods 2 which have different sizes or shapes.

Thus, in the present disclosure, the first semiconductor layer 21 and the second semiconductor layer 22 included in each of the plurality of μLEDs 220 are a bunch of one or a plurality of semiconductor rods 2 extending from the plurality of openings of the mask layer 150.

Further, in an embodiment of the present disclosure, the plurality of μLEDs 220 include a first μLED capable of emitting light at the first wavelength and a second μLED capable of emitting light at the second wavelength that is different from the first wavelength. The thickness of the plurality of semiconductor rods 2 which form the first semiconductor layer 21 and the second semiconductor layer 22 of the first μLED is different from the thickness of the plurality of semiconductor rods 2 which form the first semiconductor layer 21 and the second semiconductor layer 22 of the second μLED. In a typical embodiment, the plurality of μLEDs 220 further include a third μLED capable of emitting light at the third wavelength that is different from the first and second wavelengths. The first, second, and third wavelengths can be the center wavelengths of red, green, and blue, respectively. According to an embodiment of the present disclosure, problems in mounting of the μLEDs can be solved, and a full-color display can be realized.

In an embodiment of the present disclosure, the semiconductor rods 2 which form the second semiconductor layer 22 of each of the μLEDs 220 are located in regions defined in the mask openings 150G of the mask layer 150. As will be described later, this second semiconductor layer 22 is formed by semiconductor crystals selectively epitaxially grown from regions of the upper surface 100T of the substrate 100 which are exposed via the mask openings 150G at the start of the epitaxial growth process of the semiconductor crystals.

The thickness of the semiconductor rods 2 is defined by the size of the mask openings 150G. By adjusting the size of the mask openings 150G in every one of the μLEDs 220, the thickness of the semiconductor rods 2 included in each of the μLEDs 220 is controlled such that a desired emission color can be achieved. The reason why the emission wavelength thus varies depending on the thickness of the semiconductor rods 2 is that various parameters of the semiconductor rods 2, such as growth rate, composition, impurity concentration, strain, polarization, etc., can vary depending on the thickness of the semiconductor rods 2.

In an embodiment of the present disclosure, the device isolation region 240 includes at least one metal plug 24 electrically coupled with the second semiconductor layer 22. The metal plug 24 functions as a substrate-side electrode of the μLEDs 220. More specifically, the metal plug 24 is electrically coupled with the electrically-conductive surface of the substrate 100 via the contact opening 150C of the mask layer 150. In addition, the second semiconductor layers of the plurality of μLEDs 220 are mutually coupled via this electrically-conductive surface.

A typical example of the first semiconductor layer of the first conductivity type is a p-GaN layer. A typical example of the second semiconductor layer 22 of the second conductivity type is an n-GaN layer. Each of the p-GaN layer and the n-GaN layer does not need to have a homogeneous composition along a direction perpendicular to the upper surface 100T of the substrate 100 (semiconductor layering direction: positive direction of Z axis) but can have a multilayer structure. As previously described, Ga of GaN can be at least partially substituted with Al and/or In. Such substitution can be carried out for adjusting the bandgap and/or the refractive index of GaN. The concentration of the p-type impurity and the n-type impurity, i.e., the doping level, also does not need to be constant along the semiconductor layering direction (positive direction of Z axis).

Further, the second semiconductor layer and the first semiconductor layer may be stacked along a direction parallel to the upper surface 100T of the substrate 100 (the positive and negative directions of X axis), and each of them may have a multilayer structure. In this case also, the concentration of the p-type impurity and the n-type impurity, i.e., the doping level, also does not need to be constant along the positive and negative directions of X axis. Note that, as previously described, concurrently-growing semiconductor rods 2 can have different compositions (substitution rates) and/or impurity concentrations according to their thickness.

A typical example of the emission layer 23 include at least one InGaN well layer. When the emission layer 23 includes a plurality of InGaN well layers, a GaN barrier layer or an AlGaN barrier layer, which has a greater bandgap than the InGaN well layer, can be provided between the respective InGaN well layers. The InGaN well layer and the AlGaN barrier layer may be an InAlGaN well layer and an InAlGaN barrier layer, respectively. The bandgap of the InGaN well layer defines the emission wavelength.

Specifically, λ×Eg=1240 holds where λ [nm] is the emission wavelength in vacuum and Eg [electron volt: eV] is the bandgap. Therefore, for example, blue light at λ=450 nm can be radiated by adjusting the bandgap Eg of the InGaN well layer to about 2.76 eV. The bandgap of the InGaN well layer can be adjusted according to the In molar fraction in the InGaN well layer. When an InAlGaN well layer is used, the bandgap can be adjusted likewise according to the In molar fraction and the Al molar fraction. Generally, the In molar fraction in the InGaN well layer grown on the substrate 100 has a generally equal value across the entire surface of the substrate 100. Thus, a plurality of μLEDs 220 provided on the same substrate 100 can radiate light at generally equal wavelengths. However, according to an embodiment of the present disclosure, semiconductor rods 2 of different thicknesses are selectively epitaxially grown from a large number of mask openings 150G of different sizes and, therefore, light of a wavelength which vary depending on the thickness can be radiated from the plurality of μLEDs 220. In other words, the plurality of μLEDs 220 can include a first micro-LED capable of emitting light at the first wavelength and a second micro-LED capable of emitting light at the second wavelength that is different from the first wavelength. Also, the plurality of μLEDs 220 may further include a μLED 220 capable of emitting light at still another wavelength.

The plurality of semiconductor layers which are constituents of each μLED 220 are monocrystalline semiconductor rods 2 epitaxially grown on the substrate 100 (epitaxial semiconductor rods) or a bunch or group thereof. The device isolation region 240 is defined by a trench-like recessed portion (hereinafter, referred to as “trench”) which is realized by spaces between the bunches or groups of the plurality of semiconductor rods epitaxially grown on the substrate 100. The occupation region of each of the μLEDs 220 isolated by the trench has a size which can be included within an area of 100 μm×100 μm (e.g., area of 10 μm×10 μm). The occupation region of the μLED 220 is defined by the contour of the first semiconductor layer 21 defined by the device isolation region 240.

As shown in FIG. 1B, the device isolation region 240 surrounds each of the μLEDs 220 and isolates each of the μLEDs 220 from the other μLEDs 220. More specifically, the device isolation region 240 electrically and spatially isolate the first semiconductor layer 21 and the emission layer 23 of each of the μLEDs 220 from the first semiconductor layer 21 and the emission layer 23 of the other μLEDs 220.

In the present disclosure, the device isolation region 240 is a region which is present between the plurality of μLEDs 220 formed by selective epitaxial growth of semiconductor layers rather than a recessed portion formed by deeply etching semiconductor layers. According to an embodiment of the present disclosure, the steps of lithography or the like which are required for etching are unnecessary, and damage caused by etching to the semiconductor layers can be prevented.

In this example, the device isolation region 240 includes an embedded insulator 25 which fills the gap between the plurality of μLEDs 220. In the example illustrated in the drawing, the embedded insulator 25 also fills the gap between the semiconductor rods 2 included in each of the μLEDs 220. The embedded insulator 25 has one or a plurality of through holes for the metal plugs 24. The through holes are filled with the metal material which forms the metal plugs 24. The metal plugs 24 may have a structure formed by stacking layers of different metals.

In the example shown in FIG. 1B, a plurality of metal plugs 24 are discretely arranged, although embodiments of the present disclosure are not limited to such an example. Each of the plurality of metal plugs 24 may have a ring-like shape surrounding a corresponding one of the μLEDs 220. The metal plugs 24 may have the shape of stripes extending in parallel in one direction as shown in FIG. 1D or may be a single conductor which has the shape of a lattice as shown in FIG. 1E.

The metal plug 24 does not transmit light. Therefore, when the metal plug 24 has a shape which surrounds each of the μLEDs 220 (for example, when the metal plug 24 has the shape of FIG. 1E), the metal plug 24 produces the effect of preventing light radiated from each of the μLEDs 220 from being mixed with light radiated from the other μLEDs 220. Instead of the function of the metal plug 24 as such a light-blocking member, a light-blocking member surrounding each of the μLEDs 220 may be additionally provided in the device isolation region 240. In this way, the device isolation region 240 may have an additional function of optically isolating the emission layer 23 of each of the μLEDs 220 from the emission layers 23 of the other μLEDs 220.

In an embodiment of the present disclosure, the upper surface of the frontplane 200 is preferably planarized as shown in FIG. 1A. Such planarization is realized by making the level of the upper surfaces of the metal plug 24 and the embedded insulator 25 in the device isolation region 240 generally coincident with the level of the upper surface of the first semiconductor layer 21 in the μLEDs 220.

<Middle Layer>

The middle layer 300 includes a plurality of first contact electrodes 31 and second contact electrodes 32 (see FIG. 1A). The plurality of first contact electrodes 31 are, respectively, electrically coupled with the first semiconductor layers 21 of the plurality of μLEDs 220. At least one second contact electrode 32 is coupled with the metal plug 24.

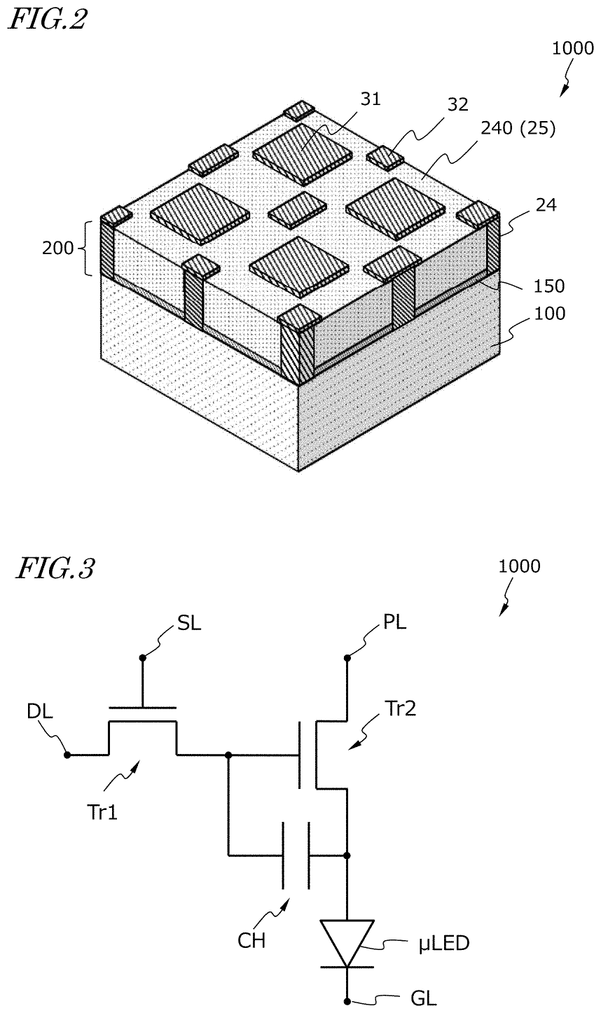

FIG. 2 is a perspective view showing an arrangement example of the first contact electrodes 31 and the second contact electrodes 32. In FIG. 2, illustration of the backplane 400 is omitted for showing the arrangement example of the contact electrodes 31, 32. The structure shown in FIG. 2 is merely a part of the μLED device 1000. As previously described, an embodiment of the μLED device 1000 includes a large number of μLEDs 220.

The second contact electrodes 32 shown in FIG. 2 are electrically coupled with the second semiconductor layer 22 via the metal plugs 24. The shape and size of the second contact electrodes 32 are not limited to the example shown in the drawing. Since the metal plugs 24 can have various shapes as previously described, the flexibility in arrangement of the second contact electrodes 32 is high so long as they are electrically coupled with the second semiconductor layer 22 via the metal plugs 24. Meanwhile, respective ones of the first contact electrodes 31 are independently electrically coupled with the first semiconductor layers 21 of the plurality of μLEDs 220. When viewed in a direction perpendicular to the upper surface 100T of the substrate 100, the shape and size of the first contact electrodes 31 do not need to be identical with the shape and size of the first semiconductor layers 21.

Since the upper surface of the frontplane 200 is planarized as previously described, the distances from the substrate 100 to the first contact electrodes 31 and the second contact electrodes 32, in other words, the “heights” or “levels” of the contact electrodes 31, 32, are mutually equal. This feature facilitates formation of the backplane 400 (described later) with the use of a semiconductor manufacture technique. In the present disclosure, the “semiconductor manufacture technique” includes the process of depositing a thin film of a semiconductor, insulator, or conductor and the process of patterning the thin film by lithography and etching. In this specification, a “planarized surface” means a surface at which the level difference caused by raised or recessed portions at the surface is not more than 300 nm. In a preferred embodiment, this level difference is not more than 100 nm.

Refer again to FIG. 1A. In the example shown in FIG. 1A, the middle layer 300 includes an interlayer insulating layer 38 which has a flat surface. The interlayer insulating layer 38 has a plurality of contact holes for respectively coupling the first and second contact electrodes 31, 32 with the electric circuit of the backplane 400. The contact holes are filled with via electrodes 36.

In an embodiment of the present disclosure, it is preferred to planarize the upper surface of the interlayer insulating layer 38 prior to formation of the backplane 400. In planarizing the insulating layer prior to, or in the middle of, formation of the backplane 400, chemical mechanical polishing (CMP) can be preferably used instead of etch back.

<Backplane>

The backplane 400 includes an electric circuit which is not shown in FIG. 1A. The electric circuit is electrically coupled with the plurality of μLEDs 220 via the plurality of first contact electrodes 31 and at least one second contact electrode 32. The electric circuit includes a plurality of thin film transistors (TFTs) and other circuit components. As will be described later, each of the TFTs includes a semiconductor layer deposited on the frontplane 200 supported by the substrate 100 and/or on the middle layer 300.

FIG. 3 is a basic equivalent circuit diagram of a sub-pixel in a case where the μLED device 1000 functions as a display device. A single pixel of the display device can include sub-pixels of different colors, for example, R, G, and B. In the example shown in FIG. 3, the electric circuit of the backplane 400 includes a selection TFT element Tr1, a driving TFT element Tr2, and a holding capacitance CH. The μLED shown in FIG. 3 is present in the frontplane 200 rather than the backplane 400.

In the example of FIG. 3, the selection TFT element Tr1 is coupled with a data line DL and a selection line SL. The data line DL is an interconnection for carrying data signals which define images to be displayed. The data line DL is electrically coupled with the gate of the driving TFT element Tr2 via the selection TFT element Tr1. The selection line SL is an interconnection for carrying signals which control the ON/OFF of the selection TFT element Tr1. The driving TFT element Tr2 controls the state of conduction between a power line PL and the μLED. When the driving TFT element Tr2 is ON, an electric current flows from the power line PL to the ground line GL via the μLED. This electric current causes the μLED to emit light. If the selection TFT element Tr1 is turned OFF, the ON state of the driving TFT element Tr2 is maintained by the holding capacitance CH.

The electric circuit of the backplane 400 can include the selection TFT element Tr1, the driving TFT element Tr2, the data line DL, the selection line SL, and other elements, although the configuration of the electric circuit is not limited to such an example.

The μLED device 1000 of the present embodiment can solely function as a display device, although a display device of a larger display area may be realized by tiling with a plurality of μLED devices 1000.

<Production Method>

Next, a basic example of the method of producing the μLED device 1000 is described.

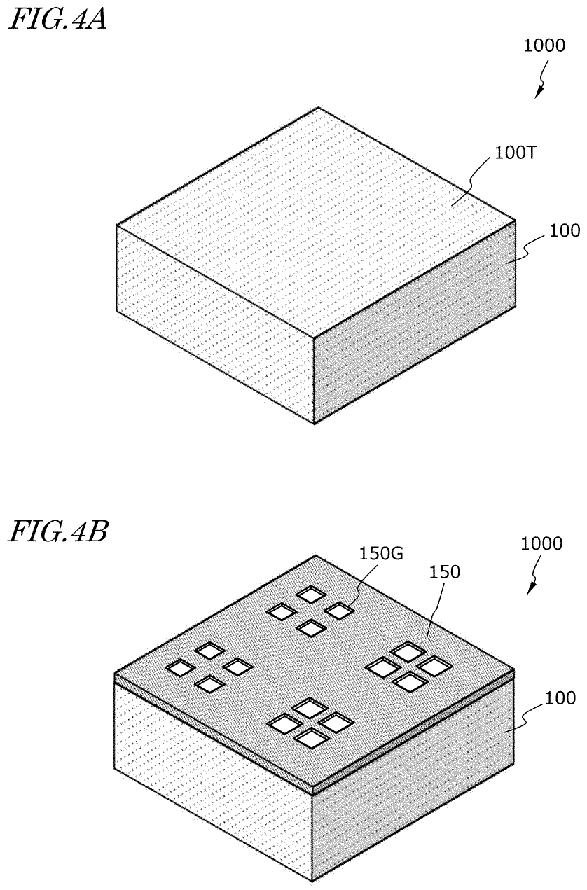

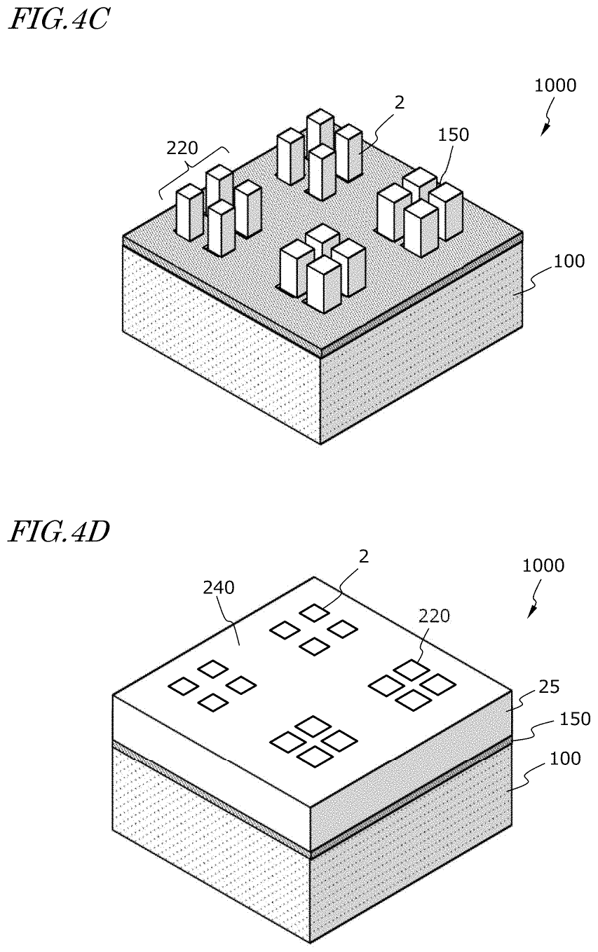

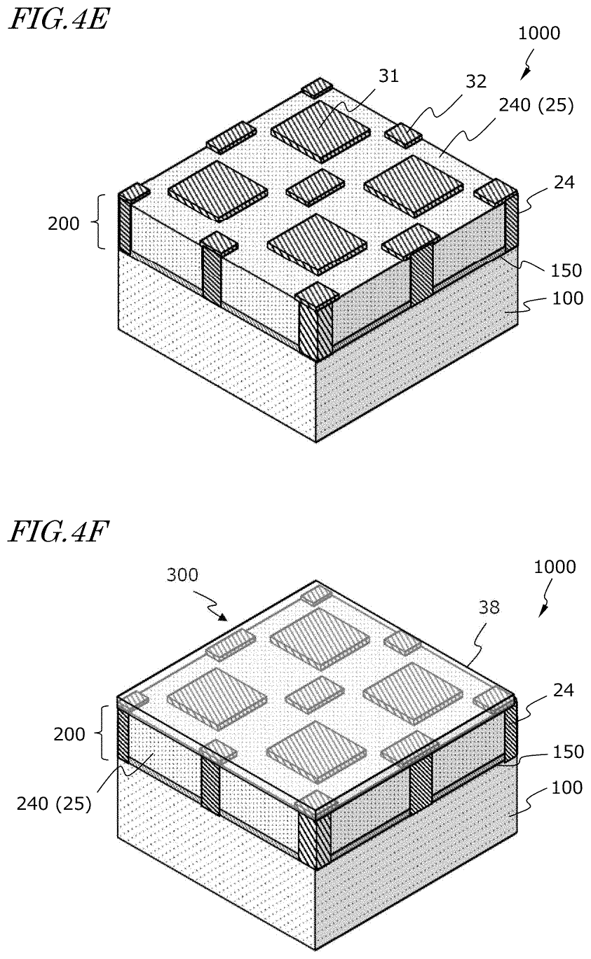

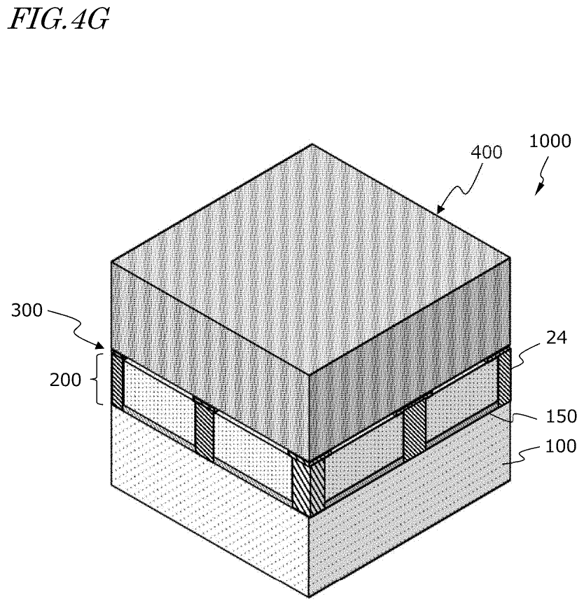

Firstly, as shown in FIG. 4A, a substrate 100 is provided which has an upper surface (crystal growth surface) 100T. FIG. 4A shows only a part of the substrate 100 extending across a plane which is parallel to the upper surface 100T. The upper surface 100T of the substrate 100 has electrical conductivity as previously described. This electrical conductivity is achieved by forming a TiN layer at the surface of the substrate 100 or doping with an impurity element of the second conductivity type.

As shown in FIG. 4B, the upper surface 100T of the substrate 100 is covered with the mask layer 150. The mask layer 150 is realized by, for example, depositing an insulating film and thereafter etching predetermined regions of the insulating film, thereby forming a plurality of mask openings 150G. The mask openings 150G partially expose the upper surface 100T of the substrate 100. When, for example, a TiN layer is located at the upper surface 100T of the substrate 100, the mask openings 150G partially expose the TiN layer.

The shape and position of the mask openings 150G define the shape and position of each of the semiconductor rods 2 of each of the μLEDs 220. In the example shown in FIG. 4B, the shape of the mask openings 150G is rectangular, although the shape of the mask openings 150G is not limited to this example. Also, the arrangement of the mask openings 150G is not limited to the example shown in FIG. 4B. In the example shown in the drawing, for the sake of simplicity, the number of mask openings 150G for each of the μLEDs 220 is four, although this number may be one to three or may be a large number which is much greater than four (for example, several hundreds or more).

As shown in FIG. 4C, a large number of semiconductor rods 2, which include the second semiconductor layer 22 of the second conductivity type, the emission layer 23, and the first semiconductor layer 21 of the first conductivity type, are epitaxially grown from exposed parts of the upper surface 100T of the substrate 100. In this step, these semiconductor rods 2 do not epitaxially grow on the mask layer 150. However, part of the second semiconductor layer 22 epitaxially grown from the mask openings 150G may grow laterally along the surface of the mask layer 150. Then, the emission layer 23 and a plurality of semiconductor layers, including the first semiconductor layer 21 of the first conductivity type, are epitaxially grown from the upper surface and the side surface of the second semiconductor layer 22. Each of the semiconductor layers is a monocrystalline epitaxially-grown layer of a gallium nitride based compound semiconductor. The epitaxial growth of the gallium nitride based compound semiconductor can be carried out by, for example, MOCVD (Metal Organic Chemical Vapor Deposition). Impurities which define each conductivity type can be introduced for doping from a gaseous phase during the crystal growth.

As a result of the above-described selective epitaxial growth, a large space (trench) can be formed between one or a plurality of semiconductor rods 2 included in each of the μLEDs 220 as shown in FIG. 4C. In this way, the trench for device isolation is formed without etching the semiconductor layers.

Then, as shown in FIG. 4D, a device isolation region 240 is formed in a space (trench) between the μLEDs 220. Specifically, the gap between adjoining semiconductor rods 2 and the trench of the device isolation region 240 are filled with an organic or inorganic insulative material, whereby an embedded insulator 25 is formed. For example, a thermosetting resin or UV-curable resin in a liquid form may be supplied onto the mask layer 150 and cured by heat or ultraviolet light. When a resin material in a liquid form is used, it is easy to form an embedded insulator 25 with a flat upper surface. Thereafter, a through hole for the metal plug (not shown in FIG. 4D) is formed at a desired position in the embedded insulator 25 using photolithography and etching techniques.

Then, after the device isolation region 240 is formed, first contact electrodes 31 and second contact electrodes 32 are formed as shown in FIG. 4E. In this example, the device isolation region 240 includes an embedded insulator 25 and a plurality of metal plugs 24 provided in a plurality of through holes of the embedded insulator 25.

After an interlayer insulating layer 38 (thickness: for example, 500 nm to 1500 nm) of the middle layer 300 is formed as shown in FIG. 4F, a plurality of contact holes (not shown in FIG. 4F) are formed in the interlayer insulating layer 38 for coupling the electric circuit of the backplane 400 with the μLEDs 220 of the frontplane 200. The contact holes are formed so as to reach the contact electrodes 31, 32 which are present in the underlying layer. The contact holes are filled with via electrodes. The upper surface of the interlayer insulating layer 38 can be planarized by CMP.

As shown in FIG. 4G, a backplane 400 is formed on the middle layer 300. A characteristic feature of the present disclosure resides in that various electronic elements and interconnections which are constituents of the backplane 400 are directly formed by a semiconductor manufacture technique on a multilayer stack which includes the frontplane 200 and the middle layer 300, rather than adhering the backplane 400 onto the middle layer 300. As a result, each of a plurality of TFTs included in the backplane 400 includes semiconductor layers deposited on the multilayer stack that includes the frontplane 200 supported by the substrate 100 and the middle layer 300.

As previously described, when the upper surface of the frontplane 200 and the upper surface of the middle layer 300 are planarized, it is easy to produce the backplane 400 which includes the TFTs by a semiconductor manufacture technique. In general, when TFTs are formed by a semiconductor manufacture technique, it is necessary to perform patterning of deposited semiconductor layers, insulating layers, and metal layers. The patterning is realized by a lithography process which involves exposure to light. If there is a large step in the underlayer of the deposited semiconductor layers, insulating layers, and metal layers, light will not be correctly focused in the exposure so that micropatterning with high precision cannot be realized. In an embodiment of the present disclosure, the entirety of the frontplane 200 including the device isolation region 240 is planarized and, accordingly, the middle layer 300 is also planarized, so that it is easy to form the backplane 400 by a semiconductor manufacture technique.

Since the shape and position of each of the semiconductor rods 2 are defined by the shape and position of the mask openings 150G of the mask layer 150, the shape and position of each of the semiconductor rods 2 and, in addition, the arrangement pattern of the μLEDs 220 can be arbitrarily controlled by adjusting the patter of the mask layer 150.

### Embodiment

Hereinafter, a basic embodiment of a μLED device of the present disclosure is described in more detail.

Refer to FIG. 5. The μLED device 1000A of the present embodiment is a display device which has the same configuration as the previously-described basic configuration example. The μLED device 1000A includes a crystal growth substrate (hereinafter, “substrate”) 100 which is capable of transmitting visible and/or ultraviolet light, a frontplane 200 provided on the substrate 100, a middle layer 300 provided on the frontplane 200, and a backplane 400 provided on the middle layer 300.

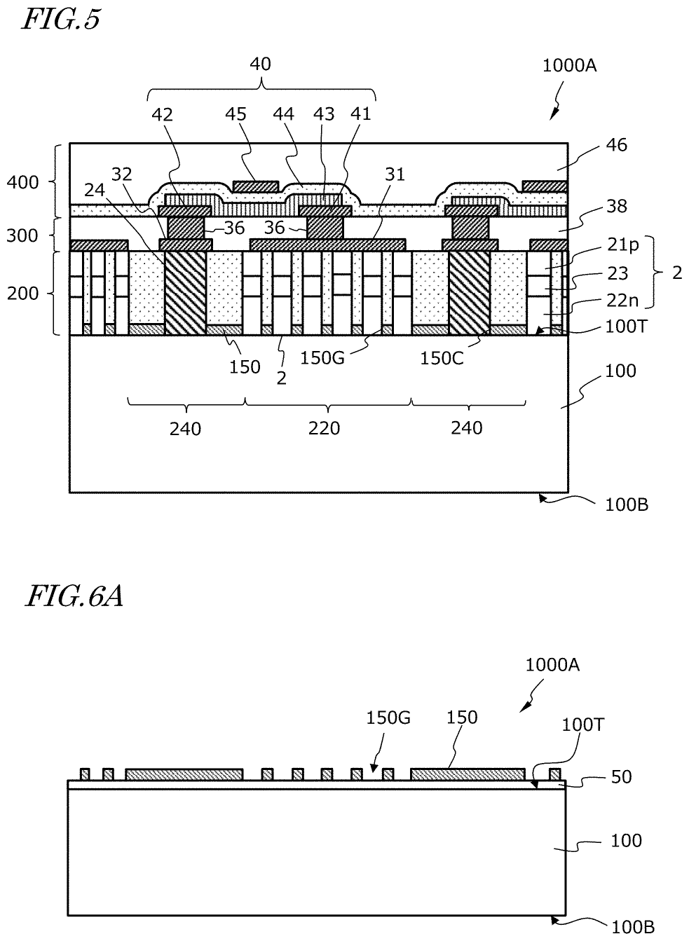

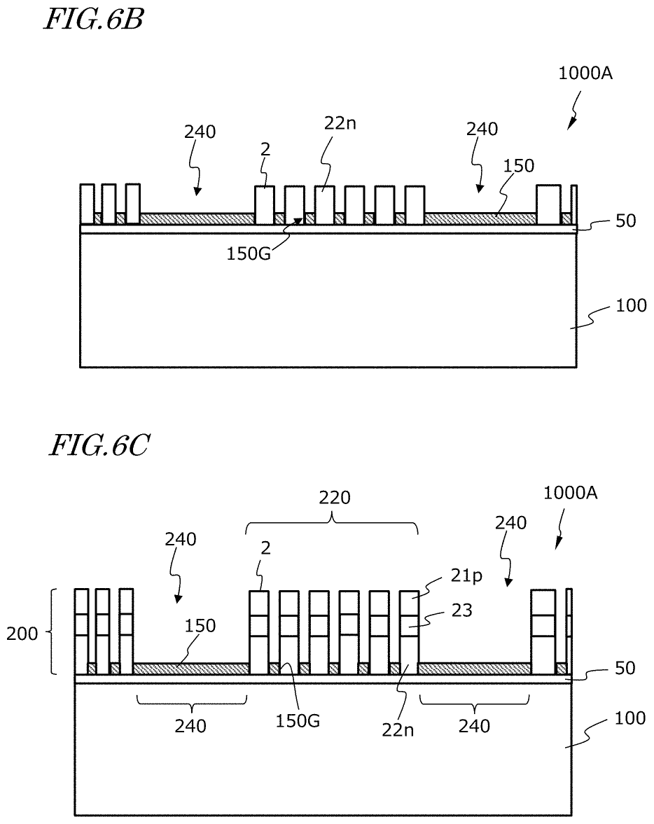

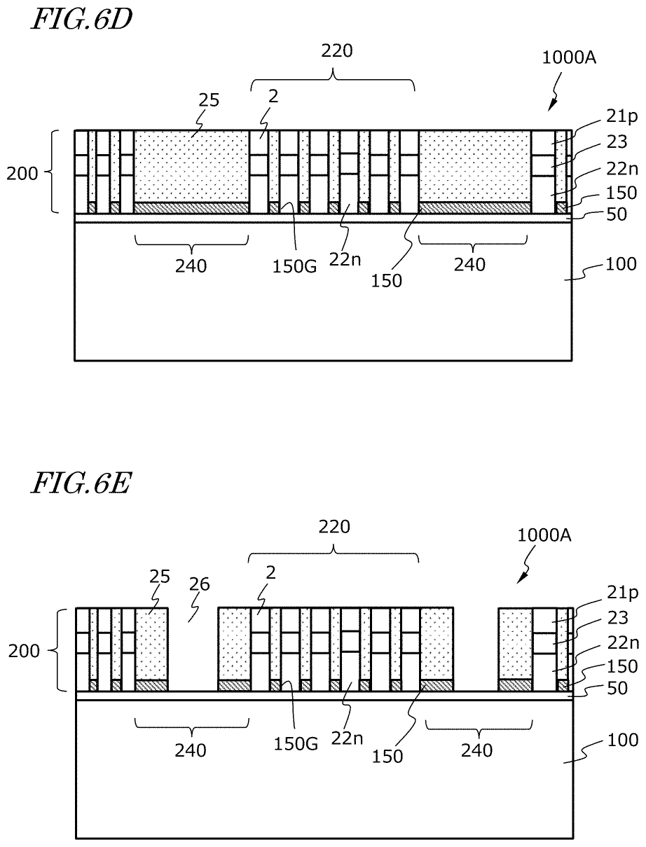

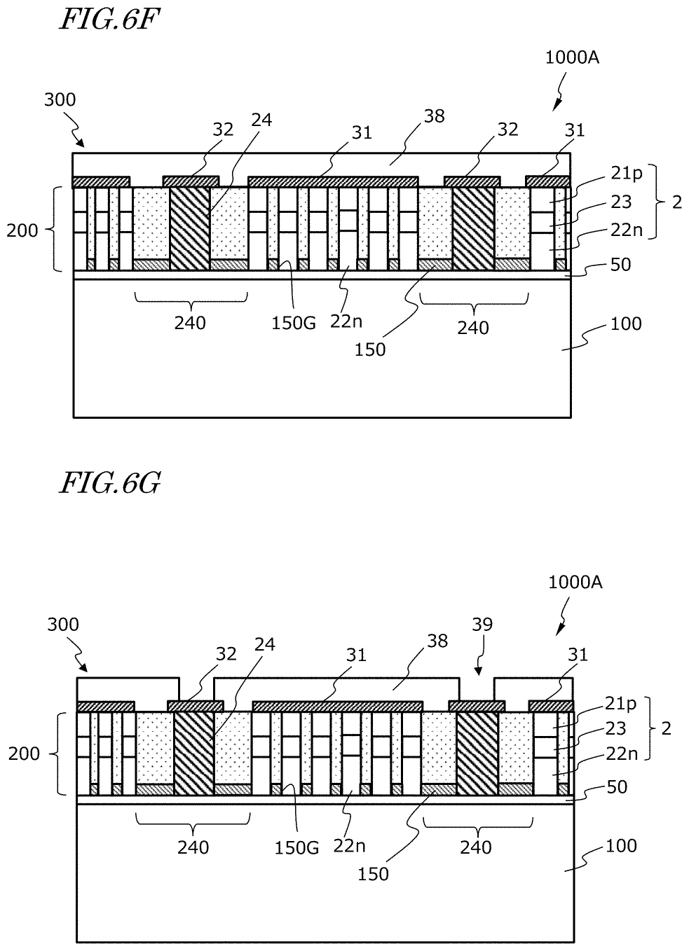

Next, an example of the configuration and production method of the μLED device 1000A of the present embodiment is described with reference to FIG. 6A through FIG. 8.

First, refer to FIG. 6A. FIG. 6A shows a configuration example of the substrate 100 used in the present embodiment. In the example shown in the drawing, a TiN layer 50 which functions as an electrically-conductive buffer layer (thickness: e.g., 5-500 nm) is located at the upper surface 100T of the substrate 100. Note that, however, when light radiated from the μLED array is transmitted through the substrate 100 and used for displaying or the like, the thickness of the TiN layer 50 is preferably in the range of 5-20 nm. An example of the electrically-conductive buffer layer is not limited to a TiN layer but may be a semiconductor layer (epilayer) of the second conductivity type. The TiN layer 50 is covered with a mask layer 150 which has mask openings 150G. The mask layer 150 can be realized by a silicon nitride or silicon oxide film which has a thickness of for example 100-1000 nm, typically 300 nm. As previously described, the mask layer 150 may be realized by a layer of a refractory metal. The mask layer 150 which is made of metal can function as part of an n-side common electrode.

After being formed by a thin film deposition technique such as sputtering, the mask layer 150 is patterned by photolithography and etching techniques. By this patterning, a plurality of mask openings 150G are formed so as to have a predetermined shape. In the present embodiment, each of the plurality of mask openings 150G determines the shape and position of the semiconductor rods 2 in each of the μLEDs 220.

In the present embodiment, a substrate 100 is placed in a reactor of a MOCVD apparatus, and various gases are supplied into the reactor for carrying out epitaxial growth of a gallium nitride (GaN) based compound semiconductor. In the present embodiment, the main body of the substrate 100 is a sapphire substrate whose thickness is, for example, about 50-600 μm. The upper surface 100T of the substrate 100 is typically a C-plane (0001), although the substrate 100 may have a nonpolar or semipolar plane, such as m-plane, a-plane, and r-plane, at the upper surface. The upper surface 100T may be inclined by about several degrees from these crystal planes. The substrate 100 typically has the shape of a circular plate. The diameter of the substrate 100 can be, for example, from 1 inch to 8 inches. The shape and size of the substrate 100 are not limited to this example. The substrate 100 may have a rectangular shape. The production process may be carried on using a substrate 100 in the shape of a circular plate, and the substrate 100 may be processed into a rectangular shape by cutting away peripheral parts of the substrate 100 in the final steps. Alternatively, the production process may be carried on using a relatively-large substrate 100, and the single substrate 100 may be divided into a plurality of μLED devices in the final steps (singulation).

Firstly, trimethyl gallium (TMG) or triethyl gallium (TEG), hydrogen (H₂) as the carrier gas, nitrogen (N₂), ammonia (NH₃), and silane (SiH₄) are supplied into the reactor of the MOCVD apparatus. The substrate 100 is heated to about 1100° C. Thereby, as shown in FIG. 6B, the n-type portion of the semiconductor rods 2 which is formed by an n-GaN layer 22n (thickness: for example, 2 μm) is selectively epitaxially grown from a region of the substrate 100 which is not covered with the mask layer 150, i.e., a region defined by the mask opening 150G. Silane is a material gas for supplying Si as the n-type dopant. The doping concentration of the n-type impurity can be, for example, 5×10¹⁷ cm⁻³.

Then, supply of SiH₄ is stopped, the substrate 100 is cooled to a temperature lower than 800° C., and an emission layer 23 is formed at the upper end of the n-type portion of the semiconductor rods 2 which is formed by the n-GaN layer 22n as shown in FIG. 6C. Specifically, firstly, a GaN barrier layer is grown. Further, supply of trimethyl indium (TMI) is started, and an In_{y}Ga_{1-y}N (0<y<1) well layer is grown. The GaN barrier layer and the In_{y}Ga_{1-y}N (0<y<1) well layer are alternately grown over two or more periods, whereby an emission layer 23 (thickness: for example, 100 nm), including a GaN/InGaN multi-quantum well which functions as the light-emitting part, can be formed. As the number of In_{y}Ga_{1-y}N (0<y<1) well layers is larger, the carrier density inside the well layers can be prevented from being excessively large in driving with a large electric current. A single emission layer 23 may include a single In_{y}Ga_{1-y}N (0<y<1) well layer interposed between two GaN barrier layers. An In_{y}Ga_{1-y}N (0<y<1) well layer may be directly formed on the n-GaN layer 22n, and a GaN barrier layer may be formed on the In_{y}Ga_{1-y}N (0<y<1) well layer. The In_{y}Ga_{1-y}N (0<y<1) well layer may include Al. For example, the In_{y}Ga_{1-y}N (0<y<1) well layer may be made of AlₓIn_{y}Ga_{z}N (0≤x<1, 0<y<1, 0<z<1).

Then, after the emission layer 23 is formed, supply of TMI is once stopped. Thereafter, nitrogen is added to the carrier gas (hydrogen), and supply of ammonia is resumed. The growth temperature is increased to a temperature in the range of 850° C. to 1000° C., and trimethyl aluminum (TMA) and biscyclopentadienyl magnesium (Cp₂Mg) as the material for Mg as the p-type dopant are supplied, whereby a p-AlGaN overflow suppression layer may be grown. Then, supply of TMA is stopped, and a p-GaN layer 21p (thickness: for example, 0.5 μm) is grown. The doping concentration of the p-type impurity can be, for example, 5×10¹⁷ cm⁻³.

According to the present embodiment, the semiconductor rods 2 that are constituents of the μLEDs 220 can be formed in an arbitrary arrangement so as to have an arbitrary shape according to the shape and arrangement of the mask openings 150G of the mask layer 150.

As shown in FIG. 6D, the spaces that define the device isolation region 240 are filled with the embedded insulator 25. The material and formation method of the embedded insulator 25 are arbitrary. In the example shown in the drawing, the upper surface of the embedded insulator 25 is planarized and located at the same level as the upper surface of the p-GaN layer 21p. In the present embodiment, a thermosetting resin is selectively dropped to the device isolation region 240 using an inkjet method and then left still for a while, whereby the surface is planarized. Thereafter, the resin is cured by heating.

As shown in FIG. 6E, through holes 26 are formed in part of the embedded insulator 25 and the mask layer 150 so as to reach the TiN layer 50. The through holes 26 define the position and shape of the metal plugs 24. The through holes 26 have, for example, a rectangular shape of 5 μm or longer on one side or a circular shape of 5 μm or longer in diameter. The through holes 26 may have a shape which is capable of containing the metal plugs 24 which have such a shape as shown in, for example, FIG. 1D and FIG. 1E.

As shown in FIG. 6F, metal plugs 24 are formed so as to fill the through holes 26, and the upper surface of the frontplane 200 is planarized. Thereafter, first contact electrodes 31 and second contact electrodes 32 are formed. The planarization can be carried out through various processes such as, for example, etch back, selective growth, CMP, or lift off.

The metal plugs 24 can be made of metal, for example, titanium (Ti) and/or aluminum (Al), such that an ohmic contact with the TiN layer 50 can be established. The metal plugs 24 preferably include a metal layer which contains Ti in a portion in contact with the n-GaN layer 22n (e.g., TiN layer). The presence of the metal layer which contains Ti contributes to realization of a low-resistance n-type ohmic contact with n-GaN or TiN. For example, the TiN layer, which is present at the interface between the metal plugs 24 and the TiN layer 50, can be formed by forming a Ti layer so as to be in contact with the TiN layer 50 and thereafter performing, for example, a heat treatment at about 600° C. for 30 seconds.

The first and second contact electrodes 31, 32 can be formed by deposition and patterning of a metal layer. Between the first contact electrodes 31 and the p-GaN layer 21p of the μLEDs 220, a metal-semiconductor interface is formed. To realize a p-type ohmic contact, the material of the first contact electrodes 31 can be selected from metals of large work function such as, for example, platinum (Pt) and/or palladium (Pd). After a layer of Pt or Pd (thickness: about 50 nm) is formed, a heat treatment can be performed at a temperature of, for example, not less than 350° C. and not more than 400° C. for about 30 seconds. So long as a layer of Pt or Pd is present in a portion which is in direct contact with the p-GaN layer 21p, a layer of a different metal, for example, a Ti layer (thickness: about 50 nm) and/or an Au layer (thickness: about 200 nm), may be formed on that layer.

In the upper part of the p-GaN layer 21p, a region doped with the p-type impurity at a relatively-high concentration may be formed. The second contact electrodes 32 are electrically coupled with the metal plugs 24 rather than the semiconductor. Therefore, the material of the second contact electrodes 32 can be selected from a wide range. The first contact electrodes 31 and the second contact electrodes 32 may be formed by patterning a single continuous metal layer. This patterning also includes lift off. If the first contact electrodes 31 and the second contact electrodes 32 have equal thicknesses, connection with the electric circuit in the backplane 400, such as TFT 40 which will be described later, will be easy.

After the first and second contact electrodes 31, are formed, these electrodes are covered with an interlayer insulating layer 38 (thickness: for example, 1000 nm to 1500 nm). In a preferred example, the upper surface of the interlayer insulating layer 38 can be planarized by CMP or the like. The thickness of the interlayer insulating layer 38 that has the planarized upper surface means “average thickness”.

As shown in FIG. 6G, contact holes 39 are formed in the interlayer insulating layer 38. The contact holes 39 are used for electrically coupling the electric circuit of the backplane 400 with the μLEDs 220 of the frontplane 200.

Hereinafter, a configuration example and formation method of TFTs included in the electric circuit of the backplane 400 are described with again reference to FIG. 5.

In the example shown in FIG. 5, the TFT 40 includes a drain electrode 41 and a source electrode 42 which are provided on the interlayer insulating layer 38, a semiconductor thin film 43 which is in contact with at least part of the upper surface of each of the drain electrode 41 and the source electrode 42, a gate insulating film 44 provided on the semiconductor thin film 43, and a gate electrode 45 provided on the gate insulating film 44. In the example shown in the drawing, the drain electrode 41 and the source electrode 42 are coupled with the first contact electrode 31 and the second contact electrode 32, respectively, via the via electrodes 36. These constituents of the TFT 40 are formed by a known semiconductor manufacture technique.

The semiconductor thin film 43 can be made of polycrystalline silicon, amorphous silicon, oxide semiconductor, and/or gallium nitride based semiconductor. The polycrystalline silicon can be formed by depositing amorphous silicon on the interlayer insulating layer 38 of the middle layer 300 by, for example, a thin film deposition technique and thereafter crystallizing the amorphous silicon with a laser beam. The thus-formed polycrystalline silicon is referred to as LTPS (Low-Temperature Poly Silicon). The polycrystalline silicon is patterned into a desired shape by lithography and etching.

In FIG. 5, the TFT 40 is covered with an insulating layer 46 (thickness: for example, 500 nm to 3000 nm). The insulating layer 46 has an unshown hole which enables coupling of, for example, the gate electrode 45 of the TFT 40 with an external driver integrated circuit device or the like. Preferably, the upper surface of the insulating layer 46 is also planarized. The electric circuit of the backplane 400 can include circuit components such as unshown TFTs, capacitors, and diodes. Thus, the insulating layer 46 may have a configuration where a plurality of insulating layers are stacked up. In this case, each of the insulating layers can include a via electrode for coupling circuit components when necessary. On each of the insulating layers, interconnections can be formed when necessary.

In the present embodiment, the backplane 400 can have the same configuration as a known backplane (e.g., TFT substrate). Note that, however, the backplane 400 of the present disclosure is characterized in that it is formed on the μLEDs 220 in the underlying layer by a semiconductor manufacture technique. Therefore, for example, the drain electrode 41 and the source electrode 42 of the TFT 40 can be formed by patterning a metal layer which is deposited so as to cover the frontplane 200. Such patterning enables high-precision aligning which is based on lithography techniques. Particularly in the present embodiment, the frontplane 200 and/or the middle layer 300 are planarized and, therefore, it is possible to increase the resolution of the lithography. As a result, it is possible to produce a device which includes a large number of μLEDs 220 aligned at a microscopic pitch of for example not more than 20 μm, in an extreme example not more than 5 μm, at a high yield and at a low cost.

The configuration of the TFT 40 shown in FIG. 5 is exemplary. For the sake of clear description, in the example described herein, the drain electrode 41 of the TFT 40 is electrically coupled with the first contact electrode 31, although the drain electrode 41 of the TFT 40 may be coupled with any other circuit component or interconnection included in the backplane 400. The source electrode 42 of the TFT 40 does not need to be electrically coupled with the second contact electrode 32. The second contact electrode 32 can be coupled with an interconnection which commonly gives a predetermined potential to the n-GaN layers 22n of the μLEDs 220 (e.g., ground interconnection).

In the present embodiment, the electric circuit of the backplane 400 includes a plurality of metal layers which are respectively coupled with the first contact electrode 31 and the second contact electrode 32 (metal layers which function as the drain electrode 41 and the source electrode 42). In the present embodiment, the plurality of first contact electrodes 31 respectively cover the p-GaN layers 21p of the plurality of μLEDs 220 and function as a light-blocking layer or a light-reflecting layer. Each of the first contact electrodes 31 does not need to cover the upper surface of the μLED 220, i.e., the entirety of the upper surface of the p-GaN layer 21p. The shape, size and position of the first contact electrodes 31 are determined such that sufficiently-low contact resistance is realized while the first contact electrodes 31 sufficiently suppress arrival of light radiated from the emission layer 23 at the channel region of the TFT 40. Prevention of arrival of light radiated from the emission layer 23 at the channel region of the TFT 40 can also be realized by arranging the other metal layers at appropriate positions.

According to an embodiment of the present disclosure, the middle layer 300 that has a planarized upper surface is formed on the frontplane 200 that has a flat upper surface which is realized by filling the device isolation region 240 with the metal plugs 24 and the embedded insulator 25. These structures (underlying structures) function as a base on which circuit components such as TFTs are to be formed. In depositing semiconductors for TFT or in performing a heat treatment after the deposition, the above-described underlying structures are treated at, for example, 350° C. or higher. Thus, the embedded insulator 25 in the device isolation region 240 and the interlayer insulating layer 38 included in the middle layer 300 are preferably made of a material which will not be degraded even by a heat treatment at 350° C. or higher. For example, polyimide and SOG (Spin-on Glass) can be suitably used.

The configuration of TFTs included in the electric circuit in the backplane 400 is not limited to the above-described examples.

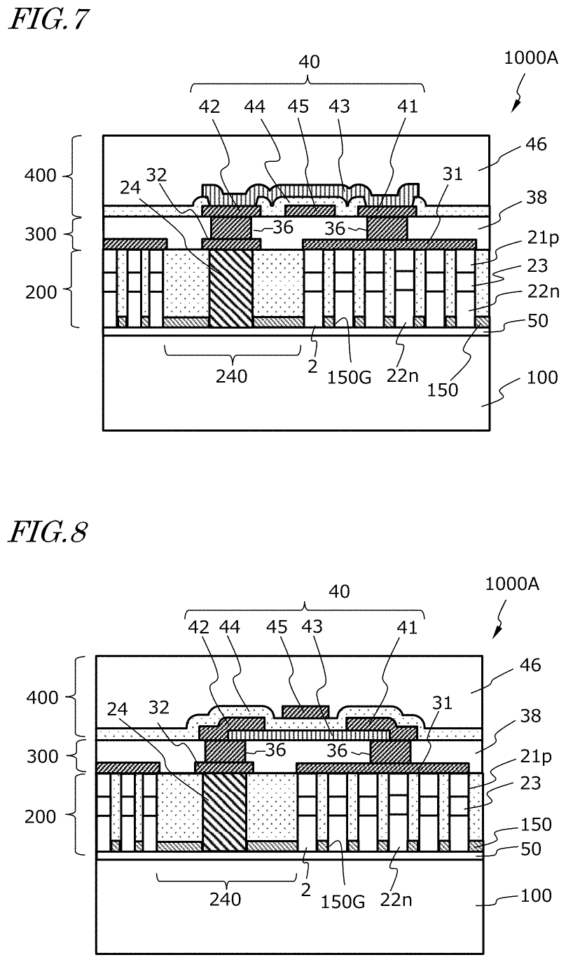

FIG. 7 is a cross-sectional view schematically showing another example of the TFT. FIG. 8 is a cross-sectional view schematically showing still another example of the TFT.

In the example of FIG. 7, the TFT 40 includes a drain electrode 41, a source electrode 42, and a gate electrode 45 which are provided on the interlayer insulating layer 38, a gate insulating film 44 which is provided on the gate electrode 45, and a semiconductor thin film 43 which is provided on the gate insulating film 44 so as to be in contact with at least part of the upper surface of each of the drain electrode 41 and the source electrode 42. In the example shown in the drawing, the drain electrode 41 and the source electrode 42 are coupled with the first contact electrode 31 and the second contact electrode 32, respectively, via the via electrodes 36.

In the example of FIG. 8, the TFT 40 includes a semiconductor thin film 43 provided on the interlayer insulating layer 38, a drain electrode 41, and a source electrode 42 which are provided on the interlayer insulating layer 38 so as to be in contact with part of the semiconductor thin film 43, a gate insulating film 44 provided on the semiconductor thin film 43, and a gate electrode 45 provided on the gate insulating film 44. In the example shown in the drawing, the drain electrode 41 and the source electrode 42 are coupled with the first contact electrode 31 and the second contact electrode 32, respectively, via the via electrodes 36.

The configuration of the TFT 40 is not limited to the above-described examples. In an embodiment of the present disclosure, in the initial phase of the process of forming the TFT 40, a plurality of metal layers are formed so as to be in contact with the first and second contact electrodes 31, 32 of the frontplane 200 via the contact holes 39 of the interlayer insulating layer 38 in the middle layer 300. These metal layers can be the drain electrode 41 or the source electrode 42 of the TFT 40 but are not limited to such examples.

In the present embodiment, the drain electrode 41 and the source electrode 42 are formed by depositing a metal layer on the interlayer insulating layer 38 in the planarized middle layer 300 and thereafter patterning the metal layer by photolithography and etching. Therefore, misalignment which can cause decrease in yield will not occur between the frontplane 200 (the middle layer 300) and the backplane 400.

When light radiated from the μLEDs 220 is transmitted through the substrate 100 and used for displaying or the like, the thickness of the TiN layer 50 can be, for example, not more than 5 nm and not less than 20 nm as previously described. The TiN layer 50 can be suitably used in combination with a substrate 100 which is made of sapphire, monocrystalline silicon or SiC, although the substrate 100 is not limited to these substrates.

The TiN layer 50 is electrically conductive. In an embodiment of the present disclosure, a large number of μLEDs 220 are arrayed over a wide area, and at least one metal plug couples the n-GaN layer 22n of the μLEDs 220 with the electric circuit of the backplane 400. Thus, if an electrical resistance component (sheet resistance) relative to the electric current flowing from the n-GaN layer 22n to the metal plug 24 is excessively high, an increase in power consumption will be caused. The TiN layer 50 functions as a buffer layer which relaxes the lattice mismatch in crystal growth and contributes to reduction in density of crystallographic defects, and also contributes to reduction in the above-described electrical resistance component in the operation of the device. The thickness of the TiN layer 50 is preferably not less than 10 nm, more preferably not less than 12 nm, from the viewpoint of reducing the electrical resistance component such that it can function as the substrate-side electrode. Meanwhile, from the viewpoint of transmitting light radiated from the μLEDs 220, the thickness of the TiN layer 50 is preferably, for example, not more than 20 nm.

Since the single continuous TiN layer 50 is electrically coupled with the n-GaN layer 22n in all of the μLEDs 220, electrical conduction between the metal plug 24 and the n-GaN layer 22n of each of the μLEDs 220 is secured. In this example, the TiN layer 50 functions as the n-side common electrode of the plurality of μLEDs 220. In an embodiment of the present disclosure, the electrodes on the second conductivity side in the plurality of μLEDs 220 are realized in a common form by a semiconductor layer or a TiN layer. Thus, a problem of conduction failure in some of the μLEDs 220 due to interconnection breakage is avoided.

The trench is filled with the embedded insulator 25. Specifically, the embedded insulator 25 can be formed by, for example, applying a resin material such as thermosetting polyimide and thereafter curing the resin material by a heat treatment at, for example, 400° C. for 60 minutes. The embedded insulator 25 does not need to be made of a resin but may be made of an inorganic insulative material such as, for example, silicon nitride, silicon oxide, or the like.

In an embodiment of the present disclosure, TFTs and other constituents included in the backplane 400 are formed in a layer lying above the frontplane 200 and the middle layer 300 by a semiconductor manufacture technique, and therefore, the frontplane 200 and the middle layer 300 need to be made of materials which are resistant to the process temperature for formation of these constituents. For example, the embedded insulator 25, the interlayer insulating layer 38 and the insulating layer 46 can be made of an organic material, but the organic material needs to be resistant to the highest temperature in the process of forming the backplane 400. Specifically, if the step of forming TFTs includes a heat treatment at a temperature higher than 300° C., for example, the embedded insulator 25, the interlayer insulating layer 38 and/or the insulating layer 46 can be made of a heat-resistant resin material which is unlikely to degrade even in a heat treatment at 300° C. (e.g., polyimide).

Each of the embedded insulator 25, the interlayer insulating layer 38 and the insulating layer 46 does not need to have a single-layer structure but may have a multilayer structure. The multilayer structure can include, for example, a stack of an organic material and an inorganic material.

In the above-described examples, the upper surface of the metal plug 24 is present at generally the same level as the upper surface of each of the μLEDs 220 and, therefore, it is possible to form circuit components such as TFTs 40 and fine interconnections on the upper surface with high precision by a semiconductor manufacture technique.

In the above-described examples, the metal plug 24 that fills the through hole 26 is used, although there can be various forms of the metal plug 24 as previously described.

### INDUSTRIAL APPLICABILITY

An embodiment of the present invention provides a novel micro-LED device. When the micro-LED device is used as a display, the micro-LED device is broadly applicable to smartphones, tablet computers, and on-board displays, and, small-, medium-, and large-sized television sets. The uses of the micro-LED device are not limited to displays.

### REFERENCE SIGNS LIST

21 . . . First semiconductor layer, 22 . . . Second semiconductor layer, 23 . . . Emission layer, 24 . . . Metal plug, 25 . . . Embedded insulator, 31″ First contact electrode, 32 . . . Second contact electrode, 36 . . . Via electrode, 38 . . . Interlayer insulating layer, 100 . . . Crystal growth substrate, 200 . . . Frontplane, 220 . . . μLED, 240 . . . Device isolation region, 300 . . . Middle layer, 400 . . . Backplane, 1000 . . . μLED device

1. A micro-LED device comprising:
a crystal growth substrate having an upper surface covered with a mask layer, the mask layer having a plurality of openings;
a frontplane supported by the crystal growth substrate, the frontplane including a plurality of micro-LEDs, each of which includes one or a plurality of semiconductor rods having a first semiconductor layer of a first conductivity type and a second semiconductor layer of a second conductivity type, and a device isolation region located between the plurality of micro-LEDs, the device isolation region including at least one metal plug electrically coupled with the second semiconductor layer;
a middle layer supported by the frontplane, the middle layer including a plurality of first contact electrodes respectively electrically coupled with the first semiconductor layer of the plurality of micro-LEDs and at least one second contact electrode coupled with the metal plug; and
a backplane supported by the middle layer, the backplane including an electric circuit electrically coupled with the plurality of micro-LEDs via the plurality of first contact electrodes and the at least one second contact electrode, the electric circuit including a plurality of thin film transistors,
wherein the crystal growth substrate has an electrically-conductive surface,
the plurality of openings of the mask layer includes a plurality of mask openings which respectively define a position of the semiconductor rods and a contact opening for coupling the metal plug with the electrically-conductive surface of the crystal growth substrate, and
each of the plurality of thin film transistors includes a semiconductor layer deposited on the frontplane and/or the middle layer.

2. The micro-LED device of claim 1, wherein
the plurality of micro-LEDs include a first micro-LED capable of emitting light at a first wavelength and a second micro-LED capable of emitting light at a second wavelength that is different from the first wavelength, and
a thickness of the plurality of semiconductor rods which form the first semiconductor layer and the second semiconductor layer of the first micro-LED is different from a thickness of the plurality of semiconductor rods which form the first semiconductor layer and the second semiconductor layer of the second micro-LED.

3. The micro-LED device of claim 1, wherein the plurality of mask openings include a plurality of first mask openings and a plurality of second mask openings each having a size and/or shape different from a size and/or shape of each of the first mask openings.

4. The micro-LED device of claim 1, wherein the mask layer is made of an electrically-conductive material and mutually electrically couples the second semiconductor layers of the plurality of micro-LEDs.

5. The micro-LED device of claim 1, wherein the crystal growth substrate includes a titanium nitride layer extending along the upper surface.

6. The micro-LED device of claim 1, wherein the crystal growth substrate includes a surface semiconductor region of the second conductivity type extending along the upper surface.

7. The micro-LED device of claim 1, wherein the device isolation region of the frontplane includes an embedded insulator filling a gap between the plurality of micro-LEDs, the embedded insulator having at least one through hole for the metal plug.

8. The micro-LED device of claim 1, wherein
the device isolation region of the frontplane includes a plurality of insulating layers covering a side surface of the plurality of micro-LEDs, and
the metal plug fills a space in the device isolation region which is surrounded by the plurality of insulating layers.

9. The micro-LED device of claim 1, wherein
the frontplane has a flat surface, and
the flat surface is in contact with the middle layer.

10. The micro-LED device of claim 1, wherein
the middle layer includes an interlayer insulating layer having a flat surface, and
the interlayer insulating layer has a plurality of contact holes for coupling the plurality of first contact electrodes and the at least one second contact electrode with the electric circuit.

11. The micro-LED device of claim 1, wherein
the electric circuit of the backplane includes a plurality of metal layers respectively coupled with the plurality of first contact electrodes and the at least one second contact electrode, and
the plurality of metal layers include at least one of a source electrode and a drain electrode of the plurality of thin film transistors.

12. The micro-LED device of claim 1, wherein each of the plurality of micro-LEDs is capable of radiating a visible, ultraviolet, or infrared electromagnetic wave.

13. A method for producing a micro-LED device, comprising:
providing a multilayer stack which includes
a frontplane supported by a crystal growth substrate which has an electrically-conductive surface, the frontplane including a plurality of micro-LEDs, each of which includes one or a plurality of semiconductor rods having a first semiconductor layer of a first conductivity type and a second semiconductor layer of a second conductivity type, and a device isolation region located between the plurality of micro-LEDs, the device isolation region including at least one metal plug electrically coupled with the second semiconductor layer, and
a middle layer supported by the frontplane, the middle layer including a plurality of first contact electrodes respectively electrically coupled with the first semiconductor layer of the plurality of micro-LEDs and at least one second contact electrode coupled with the metal plug; and
forming a backplane on the multilayer stack, the backplane including an electric circuit electrically coupled with the plurality of micro-LEDs via the plurality of first contact electrodes and the at least one second contact electrode, the electric circuit including a plurality of thin film transistors,
wherein providing the multilayer stack includes selectively epitaxially growing the semiconductor rods from a plurality of predetermined regions of an upper surface of the crystal growth substrate, and
forming the backplane includes
depositing a semiconductor layer on the multilayer stack, and
patterning the semiconductor layer deposited on the multilayer stack.

14. The method of claim 13, wherein providing the multilayer stack includes
forming a mask layer so as to cover the electrically-conductive surface of the crystal growth substrate, the mask layer having a plurality of mask openings which define a position of the semiconductor rods included in each of the plurality of micro-LEDs, and
selectively epitaxially growing the semiconductor rods from the plurality of mask openings.

15. The method of claim 14, wherein providing the multilayer stack includes, after selectively epitaxially growing the semiconductor rods from the plurality of mask openings, forming a contact opening in the mask layer for coupling the metal plug with the electrically-conductive surface of the crystal growth substrate.

16. The method of claim 13, wherein the mask openings have a size determined according to an emission wavelength of each of the micro-LEDs.
